(19) United States
(12) Patent Application Publication
(10) Pub. No.: US 2026/0136497 A1
(43) Pub. Date: May 14, 2026

(54) DESICCANT BOX MODULE AND IMMERSION COOLING APPARATUS INCLUDING THE SAME

(71) Applicant: Wiwynn Corporation, New Taipei City (TW)

(72) Inventors: Hsien-Chieh HSIEH, New Taipei City (TW); Fu Sheng Cheng, New Taipei City (TW); Tsung-Han Li, New Taipei City (TW); Jing-Suei Gao, New Taipei City (TW)

(21) Appl. No.: 19/219,225

(22) Filed: May 27, 2025

Related U.S. Application Data
(60) Provisional application No. 63/717,960, filed on Nov. 8, 2024.

(30) Foreign Application Priority Data
Feb. 21, 2025 (TW) 114106476

(51) Int. Cl. H05K 7/20

(52) U.S. Cl. CPC H05K 7/203; H05K 7/20318; H05K 7/20327

(57) ABSTRACT

A desiccant box module includes a case configured to contain a desiccant. The case includes a case inner frame, a case mesh sheet and a case outer frame. The case mesh sheet is sandwiched between the case outer frame and the case inner frame. A plurality of first ventilation holes are formed on the case mesh sheet. A size of the first ventilation hole is smaller than a size of particle of the desiccant.

This application claims priority under 35 U.S.C. § 119(e) on U.S. Provisional Application No(s). 63/717,960 filed on November 8, 2024, and under 35 U.S.C. § 119(a) on Patent Application No(s). 114106476 filed in Taiwan, R.O.C. on Feb. 21, 2025, the entire contents of which are hereby incorporated by reference.

### BACKGROUND

### 1. Technical Field

The present disclosure is related to a desiccant box module and an immersion cooling apparatus.

### 2. Related Art

Coolant plays a very important role for immersion cooling technology. The coolant suffers from acidification or chemical changes when exposed to water, which may cause corrosion, damage or additional problems to the electronic parts immersed therein. In order to prevent an increased cost due to frequent replacement of coolant, the desiccant box can be placed in the tank containing the coolant to absorb moisture to therefore alleviate acidification or chemical changes when the coolant is exposed to water.

However, the desiccant box should be breathable to design with ventilation holes, but the ventilation holes reduce the structural strength of the desiccant box. Therefore, how to meet the requirements for breathability and structural strength of the desiccant box has become a goal in the related field.

### SUMMARY

It is therefore an objective of the present disclosure to provide a desiccant box module and an immersion cooling apparatus which can meet the requirements for breathability and structural strength.

According to one embodiment of the present disclosure, a desiccant box module includes a case configured to contain a desiccant. The case includes a case inner frame, a case mesh sheet and a case outer frame. The case mesh sheet is sandwiched between the case outer frame and the case inner frame. A plurality of first ventilation holes are formed on the case mesh sheet. A size of the first ventilation hole is smaller than a size of particle of the desiccant.

According to another embodiment of the present disclosure, an immersion cooling apparatus includes a tank and the aforementioned desiccant box module. The desiccant box module is disposed in the tank.

The desiccant box module and the immersion cooling apparatus have the following advantages: (1) the mesh sheet with holes is sandwiched between the outer frame and the inner frame, which meets the requirements for breathability and structural strength; (2) multiple trays are disposed in the desiccant box module to contain the desiccant, which prevents the desiccant from being over compact and increases moisture absorption surface area; (3) the gap between adjacent trays is greater than or equal to the length that one handle extends beyond the tray, which prevents the desiccant from being over compact and increases moisture absorption surface area; and (4) the fan assembly increases the air flow rate through the trays so as to enhance the effect of absorbing water vapor.

### BRIEF DESCRIPTION OF THE DRAWINGS

FIG. 1 is a perspective view of part of an immersion cooling apparatus according to one embodiment of the present disclosure;

FIG. 2 is a side view of part of the immersion cooling apparatus in FIG. 1;

FIG. 3 is a perspective view of the desiccant box module in FIG. 1;

FIG. 4 is an exploded view of the desiccant box module in FIG. 3;

FIG. 5 is an exploded view of the case in FIG. 4 with structure for ventilation;

FIG. 6 is an exploded view of the tray in FIG. 4;

FIG. 7 is a cross-sectional view of the desiccant box module in FIG. 3;

FIG. 8 is a cross-sectional view of a desiccant box module according to another embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present disclosure. The following embodiments further illustrate various aspects of the present disclosure, but are not meant to limit the scope of the present disclosure.

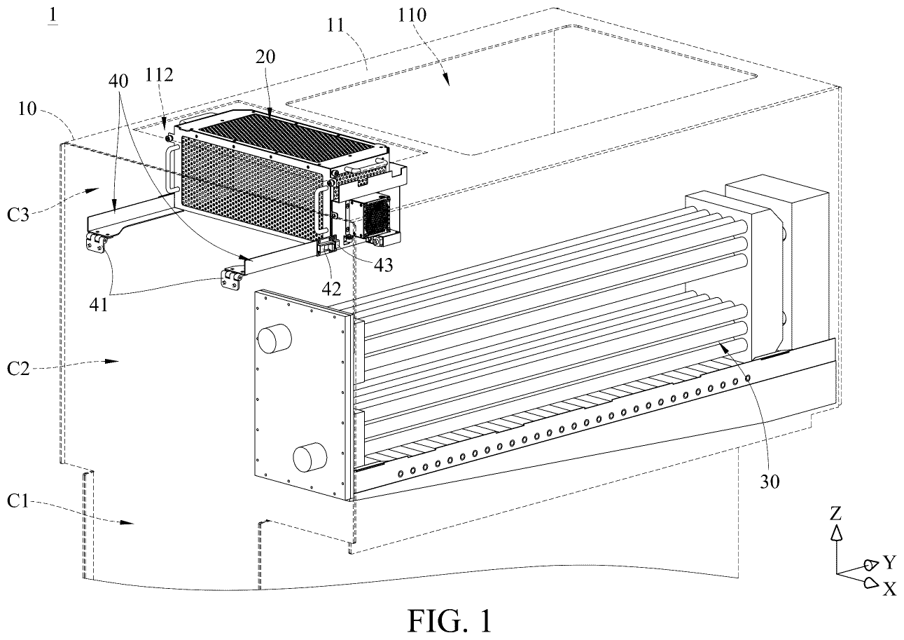

FIG. 1 is a perspective view of part of an immersion cooling apparatus 1 according to one embodiment of the present disclosure. The immersion cooling apparatus 1 includes a tank 10, a desiccant box module 20 and a condenser module 30. A non-conductive liquid coolant (not shown in the drawings) can be injected into the tank 10, and the liquid coolant evaporates into coolant vapor after absorbing heat generated by electronic components (such as servers, not shown in the drawings). The electronic components may be disposed in the tank 10 or connected to another tank of the tank 10. Since the coolant does not completely fill the tank 10, the tank 10 contains air. The desiccant box module 20 is disposed in the tank 10 and configured to absorb water vapor from the air. The condenser module 30 is disposed in the tank 10 and configured to condense the coolant vapor into liquid coolant.

It should be understood that since gravity is proportional to mass, the substance with greater mass or density will move to the bottom of the tank 10 due to gravity, while the substance with less mass or density will move to the top of the tank 10 due to buoyancy and the reaction force of any moving substance. Furthermore, since the liquid coolant has a greater density than that of the coolant vapor and the coolant vapor has a greater molecular weight than those of air and water vapor, a liquid region C1, a vapor region C2 and an air region C3 are naturally formed in the tank 10. The liquid region C1 has the lowest altitude, the air region C3 has the highest altitude, and the vapor region C2 is between the liquid region C1 and the air region C3. Thus, the condenser module 30 is disposed in the vapor region C2 to condense vapor, and the desiccant box module 20 is disposed in the air region C3 to absorb water vapor, such that the acidification or chemical changes due to the exposure of coolant and coolant vapor to water can be alleviated.

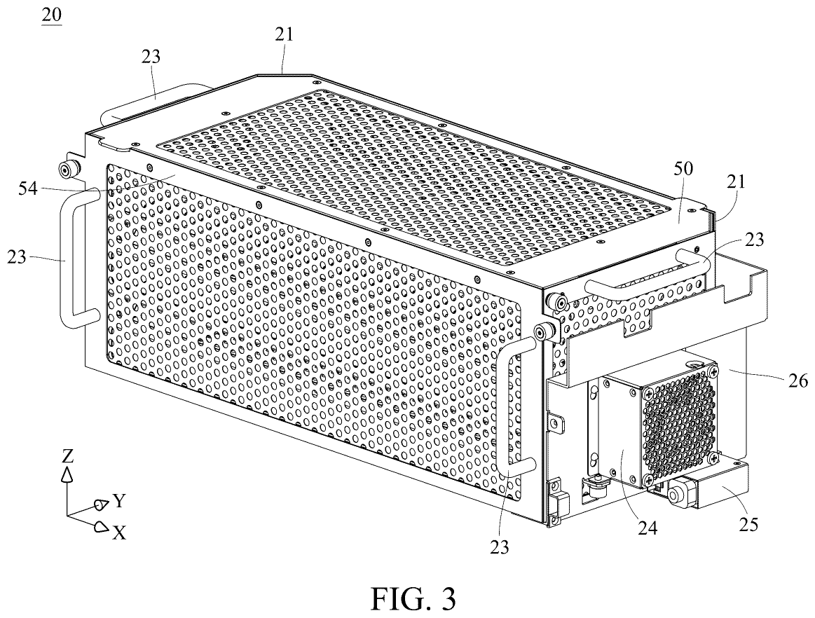

A first opening 110 is formed on the upper surface 11 of the tank 10, and a staff can install or repair the condenser module 30 through the first opening 110. The tank 10 further includes a first lid (not shown in the drawings) for sealing the first opening 110. A projection of the first opening 110 overlaps with a projection of the condenser module 30 onto the X-Y plane, and the projection of the first opening 110 does not overlap with a projection of the desiccant box module 20 onto the X-Y plane. Also, a second opening 112 is formed on the upper surface 11 of the tank 10, and the staff can install or repair the desiccant box module 20 through the second opening 112. The tank 10 further includes a second lid (not shown in the drawings) for sealing the second opening 112. A projection of the second opening 112 overlaps with the projection of the desiccant box module 20 onto the X-Y plane. In one embodiment, an area of the first opening 110 is larger than that of the second opening 112. The staff can select either the first opening 110 or the second opening 112 to install or repair parts according to the area and volume of said parts, which reduces the escape of non-conductive coolant. For example, the staff can install or repair an electronic device through the first opening 110 with larger area, and can install or repair the desiccant box module 20 as well as the presence sensor 25 (see FIG. 3) through the second opening 112 with smaller area. In other embodiments, the tank 10 may only include the first opening 110, such that the staff can install or repair the desiccant box module 20 as well as the condenser module 30 through the first opening 110. In such a case, the projections of the first opening 110 and the desiccant box module 20 onto the X-Y plane may overlap so as to facilitate the operation.

In one embodiment, the immersion cooling apparatus 1 further includes two brackets 40. An end of each of the two brackets 40 is fixed to an inner wall of the tank 10 parallel to the X-Z plane and configured to support the desiccant box module 20. Each of the two brackets 40 include a hinge 41 disposed adjacent to the inner wall of the tank 10 parallel to the X-Z plane. A pin of the hinge 41 is parallel to the X-axis direction, such that the two brackets 40 are pivotable around X-axis. Each of the two brackets 40 further includes a holder (not shown in the drawings) fixed to an inner wall of the tank 10 parallel to the Y-Z plane and configured to keep the brackets 40 in the Y-axis direction. In other embodiments, the pin of the hinge 41 is parallel to the Z-axis direction, such that the two brackets 40 are pivotable around the Z-axis direction. Therefore, in a condition that the desiccant box module 20 is not assembled to the brackets 40, the brackets 40 can be folded to facilitate the operation of installing parts on or detaching parts from the tank 10. Also, the two brackets 40 are optional elements; in other embodiments, the desiccant box module 20 may be assembled to the tank 10 by any other suitable elements such as hooks or shelves.

In one embodiment, each of the two brackets 40 includes a latch 42, and the desiccant box module 20 includes two catches 43. In operation, the desiccant box module 20 is placed into the tank 10 along the Z-axis direction, then the desiccant box module 20 is moved to the brackets 40 along the Y-axis direction, and finally the two latches 42 are inserted into the two catches 43, such that the desiccant box module 20 is fixed to the two brackets 40.

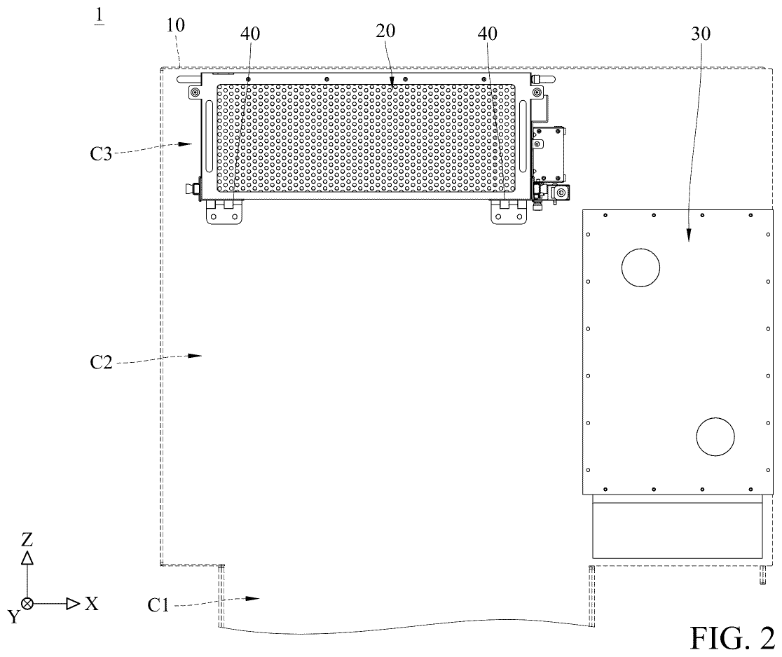

FIG. 2 is a side view of part of the immersion cooling apparatus in FIG. 1. As can be seen from FIG. 2, the projections of the desiccant box module 20 and the condenser module 30 onto the X-Y plane does not overlap. In other words, in the Z-axis direction, the desiccant box module 20 is not located directly above the condenser module 30 so as to facilitate the operation of installing and repairing. In other embodiments, in a condition that the tank 10 with limited space, the projections of the desiccant box module 20 and the condenser module 30 onto the X-Y plane may partially overlap or completely overlap, as long as the desiccant box module 20 is in the air region C3.

FIG. 3 is a perspective view of the desiccant box module in FIG. 1. The desiccant box module 20 includes a cover 50 and a case 54. The case 54 is configured to contain the desiccant (not shown in the drawings). The cover 50 is disposed on the case 54 and configure to prevent the desiccant from falling outside of the case 54.

In one embodiment, each of the projections of the cover 50 and the case 54 onto the X-Y plane has a shape of snip-same-side-corner-rectangle. That is, two guiding surfaces 21 are formed at the same side corners of the cover 50 and the case 54. The guide surface 21 may be an inclined surface or a curved surface so as to guide the desiccant box module 20 sliding into the brackets 40.

In one embodiment, the desiccant box module 20 further includes a plurality of handles 23 disposed on at least one outer surface of the case 54 to be handy for picking up the desiccant box module 20. However, the handle 23 is an optional element and may be omitted in other embodiments.

In one embodiment, the desiccant box module 20 further includes a fan assembly 24 disposed on an outer surface (e.g., one of the four lateral surfaces) of the case 54 and configured to increase the flow rate of air passing through the case 54.

In one embodiment, the desiccant box module further includes a presence sensor 25 disposed on an outer surface of the case 54, and configured to sense whether the desiccant box module 20 is assembled in the tank 10.

In one embodiment, the desiccant box module 20 further includes an assembling frame 26, and the fan assembly 24 as well as the presence sensor 25 are attached to an outer surface of the case 54 via the assembling frame 26. In other embodiments, the fan assembly 24 and the presence sensor 25 may be directly attached to the outer surface of the case 54. However, the assembling frame 26, the fan assembly 24 and the presence sensor 25 are optional elements and may be omitted in other embodiments.

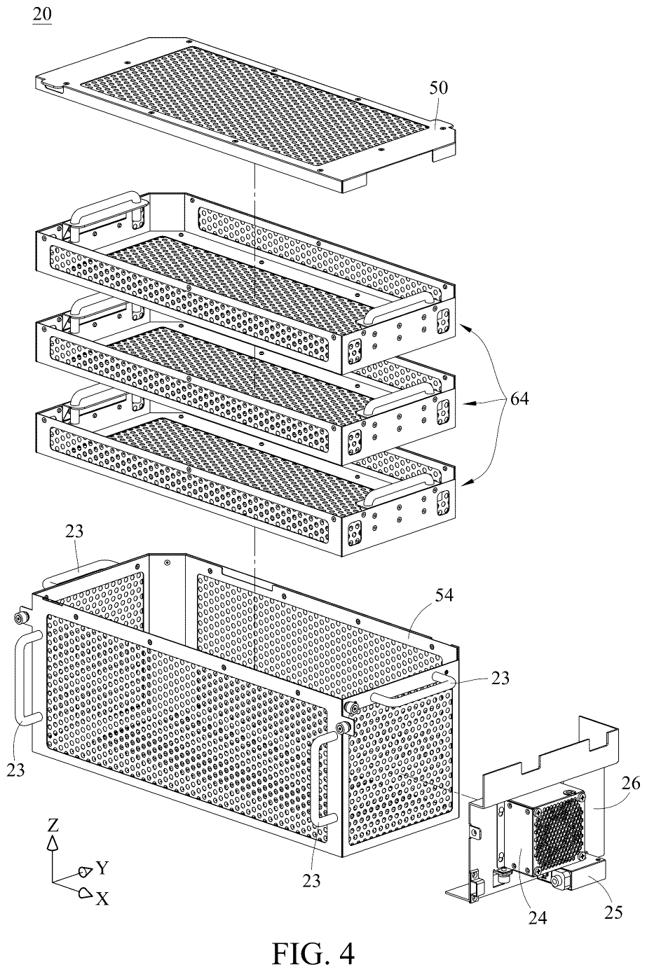

FIG. 4 is an exploded view of the desiccant box module in FIG. 3. In one embodiment, the desiccant box module 20 further includes a plurality of trays 64 disposed in the case 54. The trays 64 are arranged parallel to the bottom surface (X-Y plane) of the case 54 and configured to contain the desiccant. Noticeably, the bared or bagged desiccant may be distributed in the trays 64, which not only facilitates installation and maintenance but also prevents the desiccant from being over compact and increases moisture absorption surface area. It should be understood that the trays 64 are optional elements and may be omitted in other embodiment, such that the desiccant may be directly placed in the case 54.

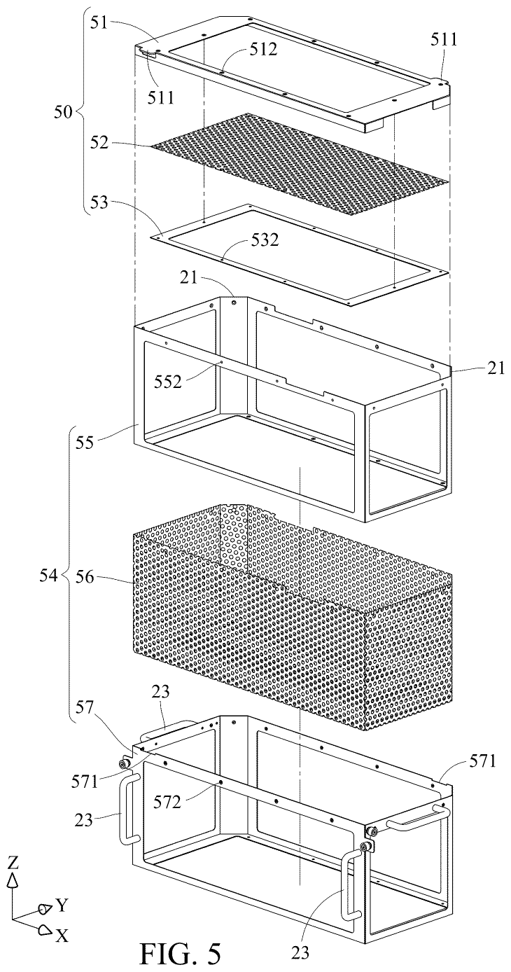

FIG. 5 is an exploded view of the case in FIG. 4 with structure for ventilation. The cover 50 includes a cover outer frame 51, a cover mesh sheet 52 and a cover inner frame 53. The cover mesh sheet 52 is sandwiched between the cover outer frame 51 and the cover inner frame 53.

In one embodiment, the cover outer frame 51 includes a plurality of flanges 511 provided at different edges of the cover outer frame 51, and the flanges 511 respectively correspond to a plurality recesses 571 formed on the case outer frame 57 of the case 54. When the cover 50 covers the case 54, the flanges 511 of the cover 50 respectively fit in the recesses 571 of the case 54 so as to prevent the cover 50 from falling into the case 54.

In one embodiment, a plurality of holes 512 are formed on the cover outer frame 51, and a plurality of corresponding holes 532 are formed on the cover inner frame 53. The desiccant box module 20 further includes a plurality of fasteners (not shown in the drawings) such as screws with nuts, double-cap rivets and the like. In operation, the screws can pass through the holes 512, 532 along the Z-axis direction and then be fastened with the nuts to fix the cover outer frame 51 to the cover inner frame 53, but the present disclosure is not limited thereto.

On the other hand, the case 54 includes a case outer frame 57, a case mesh sheet 56 and a case inner frame 55. The case mesh sheet 56 is sandwiched between the case outer frame 57 and the case inner frame 55.

In one embodiment, a plurality of holes 552 are formed on the case outer frame 57, and a plurality of corresponding holes 572 are formed on the case inner frame 55. The desiccant box module 20 further includes a plurality of fasteners (not shown in the drawings) such as screws with nuts, double-cap rivets and the like. In operation, the screws can pass through the holes 552, 572 along the Y-axis direction and then be fastened with the nuts to fix the case outer frame 57 to the case inner frame 55, but the present disclosure is not limited thereto.

In one embodiment, the case mesh sheet 56 may be formed in one-piece or composite of multiple mesh sheets. In one embodiment, a plurality of ventilation holes are formed on the cover mesh sheet 52 and the case mesh sheet 56. The ventilation hole may be circular, rectangular or triangular, but the present disclosure is not limited thereto. In one embodiment, the size of the ventilation hole of the cover mesh sheet 52 and the case mesh sheet 56 is smaller than the size of particles of the desiccant so as to prevent the desiccant particles in the case 54 from falling outside of case 54 through the ventilation holes. For example, the ventilation hole size of less than 1.5 mm is smaller than the desiccant particle size of approximately 2 mm to 4 mm. In one embodiment, the cover mesh sheet 52 and the case mesh sheet 56 may be made of metal, plastic, or a combination thereof.

In one embodiment, the stiffness of the cover outer frame 51 and the case outer frame 57 is greater than or equal to the stiffness of the cover inner frame 53 and the case inner frame 55. The stiffness of the cover inner frame 53 and the case inner frame 55 is greater than or equal to the stiffness of the cover mesh sheet 52 and the case mesh sheet 56. This configuration is favorable for meeting both the requirements for breathability and structural strength of the desiccant box 20.

In this embodiment, the desiccant box module 20 is a rectangular box with openwork, and thus the cover outer frame 51 and the cover inner frame 53 are rectangular frames, and the case outer frame 57 and the case inner frame 55 are cubic frames. However, in other embodiments, the desiccant box module 20 may have other geometric shapes such as sphere, cylinder, polygon and the like. Any person skilled in the art can select and design the shapes of the inner and outer frames based on specific requirements. Moreover, based on different requirements of structural strength, any surface of the desiccant box module 20 may have single window, multiple windows or no window. For example, a surface of the desiccant box module 20 corresponding to the guide surface 21 may have no window.

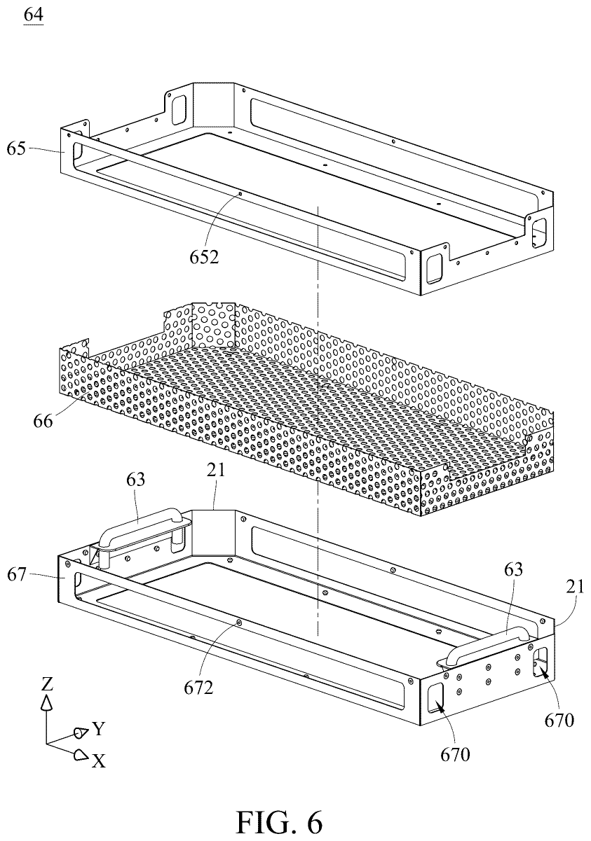

FIG. 6 is an exploded view of the tray in FIG. 4. The tray 64 is similar to a sieve or a strainer, and the tray 64 includes a tray outer frame 67, a tray mesh sheet 66 and a tray inner frame 65. The tray mesh sheet 66 is sandwiched between the tray outer frame 67 and the tray inner frame 65.

In one embodiment, a plurality of holes 672 are formed on the tray outer frame 67, and a plurality of corresponding holes 652 are formed on the tray inner frame 65. The desiccant box module 20 further includes a plurality of fasteners (not shown in the drawings) such as screws with nuts, double-cap rivets and the like. In operation, the screws can pass through the holes 672, 652 along the Y-axis direction and then be fastened with the nuts to fix the tray outer frame 67 to the tray inner frame 65, but the present disclosure is not limited thereto.

In one embodiment, each tray 64 includes a plurality of handles 63 disposed on the inner surfaces of the tray outer frame 67. For example, the handles 63 are disposed on two inner surfaces parallel to the Y-Z plane.

In one embodiment, the tray mesh sheet 66 may be formed in one-piece or composite of multiple mesh sheets. In one embodiment, a plurality of ventilation holes are formed on the tray mesh sheet 66. The ventilation hole may be circular, rectangular or triangular, but the present disclosure is not limited thereto. In one embodiment, the size of the ventilation hole of the tray mesh sheet 66 is smaller than the size of particles of the desiccant so as to prevent the desiccant particles in the trays 64 from falling out through the ventilation holes. For example, the ventilation hole size of less than 1.5 mm is smaller than the desiccant particle size of approximately 2 mm to 4 mm. In one embodiment, the tray mesh sheet 66 may be made of metal, plastic, or a combination thereof.

It should be understood that based on different requirements of structural strength, any surface of the tray 64 may have single window, multiple windows or no window. Take the tray outer frame 67 as an example, a surface of the tray outer frame 67 corresponding to the guide surface 21 may have no window, and another surface thereof corresponding to the handle 63 may have two windows.

In one embodiment, the stiffness of the tray outer frame 67 is greater than or equal to the stiffness of the tray inner frame 65. The stiffness of the tray inner frame 65 is greater than or equal to the stiffness of the tray mesh sheet 66. This configuration is favorable for meeting both the requirements for breathability and structural strength of the tray 64.

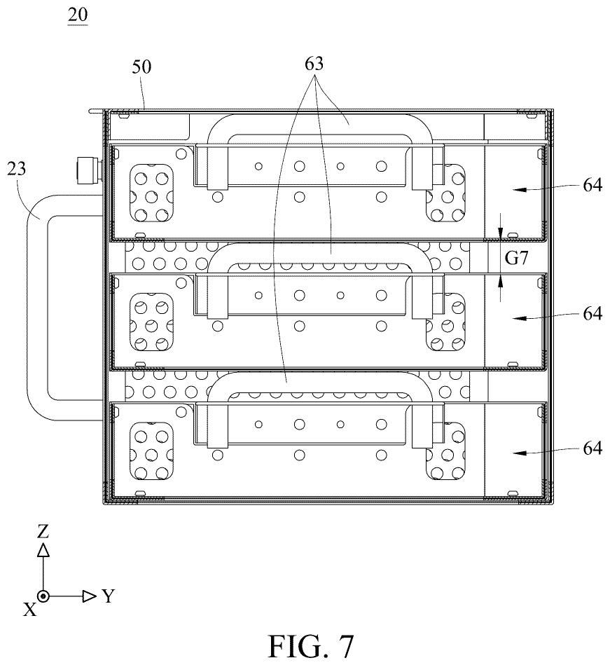

FIG. 7 is a cross-sectional view of the desiccant box module in FIG. 3. In the Z-axis direction, a gap G7 between two of the trays 64 is greater than or equal to a length that one of the handles 63 extends beyond the tray 64. Selecting the gap G7 properly can prevent the desiccant from being over compact and increase moisture absorption surface area. Further, the air flow rate through the trays 64 is increased by the fan assembly 24 (not shown in FIG. 7), thereby enhancing the effect of absorbing water vapor.

According to the embodiment depicted in FIG. 1 through FIG. 7, the cover 50 is located on the upper surface of the desiccant box module 20 and parallel to the X-Y plane, such that the staff can place or remove the trays 64 through the upper surface of the desiccant box module 20. However, in other embodiments, the cover 50 may be located on the lateral surface of the desiccant box module 20 and parallel to the Y-Z plane or X-Z plane, such that the trays 64 can be extracted out through the lateral surface of the desiccant box module 20.

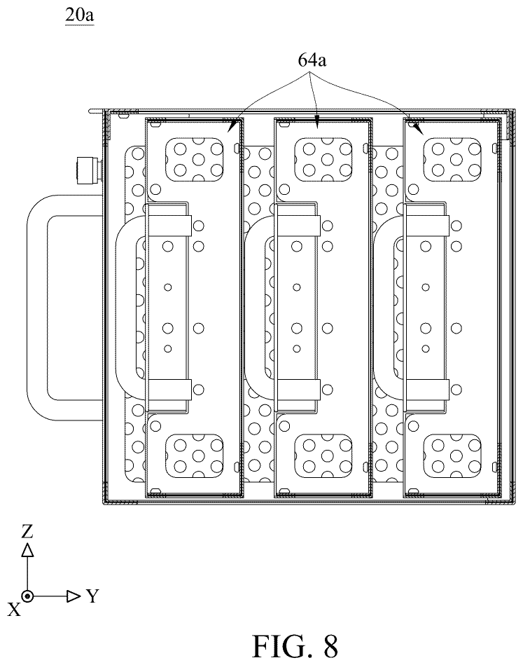

FIG. 8 is a cross-sectional view of a desiccant box module according to another embodiment of the present disclosure. In the desiccant box module 20a as shown in FIG. 8, a plurality of trays 64a are arranged parallel to the lateral surface (X-Z plane) of the case 54. In contrast, in the desiccant box module 20 as shown in FIG. 7, the trays 64 are arranged parallel to the bottom surface (X-Y plane) of the case 54. That is to say, the trays 64a in FIG. 8 are placed in a vertical orientation, while the trays 64 in FIG. 7 are placed in a horizontal orientation. The desiccant box module 20a in FIG. 8 is similar to the desiccant box module 20 from FIG. 1 through FIG. 7, and detailed description regarding the same parts is omitted.

To sum up, the desiccant box module and the immersion cooling apparatus of the present disclosure have the following advantages: (1) the mesh sheet with holes is sandwiched between the outer frame and the inner frame, which meets the requirements for breathability and structural strength; (2) multiple trays are disposed in the desiccant box module to contain the desiccant, which prevents the desiccant from being over compact and increases moisture absorption surface area; (3) the gap between adjacent trays is greater than or equal to the length that one handle extends beyond the tray, which prevents the desiccant from being over compact and increases moisture absorption surface area; and (4) the fan assembly increases the air flow rate through the trays so as to enhance the effect of absorbing water vapor.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A desiccant box module, comprising:
a case configured to contain a desiccant, wherein the case comprises a case inner frame, a case mesh sheet and a case outer frame, the case mesh sheet is sandwiched between the case outer frame and the case inner frame, a plurality of first ventilation holes are formed on the case mesh sheet, and a size of the plurality of first ventilation holes is smaller than a size of particles of the desiccant.

2. The desiccant box module according to claim 1, further comprising:
a cover disposed on the case and configured to prevent the desiccant from falling outside of the case, wherein the cover comprises a cover outer frame, a cover mesh sheet and a cover inner frame, the cover mesh sheet is sandwiched between the cover outer frame and the over inner frame, a plurality of second ventilation holes are formed on the cover mesh sheet, and a size of the plurality of second ventilation holes is smaller than the size of the particles of the desiccant.

3. The desiccant box module according to claim 2, wherein each of the cover outer frame and the case outer frame has a first stiffness, each of the cover inner frame and the case inner frame has a second stiffness, the first stiffness is greater than or equal to the second stiffness, each of the cover mesh sheet and the case mesh sheet has a third stiffness, and the second stiffness is greater than or equal to the third stiffness.

4. The desiccant box module according to claim 2, wherein
the cover outer frame comprises a plurality of flanges at different edges of the cover outer frame, and
a plurality of recesses are formed on the case outer frame and respectively correspond to the plurality of flanges, the plurality of flanges respectively fit in the plurality of recesses when the cover covers the case.

5. The desiccant box module according to claim 1, further comprising a plurality of first handles disposed on at least one outer surface of the case.

6. The desiccant box module according to claim 1, further comprising a fan assembly disposed on an outer surface of the case and configured to increase a flow rate of air passing through the case.

7. The desiccant box module according to claim 6, further comprising a presence sensor disposed on an outer surface of the case and configured to sense whether the desiccant box module is assembled in a tank.

8. The desiccant box module according to claim 7, further comprising an assembling frame disposed on the outer surface of the case, wherein the fan assembly and the sensor are disposed on the outer surface of the case via the assembling frame.

9. The desiccant box module according to claim 1, further comprising a plurality of trays disposed in the case and configured to contain portions of the desiccant.

10. The desiccant box module according to claim 9, wherein each of the plurality of trays comprises a tray outer frame, a tray mesh sheet and a tray inner frame, the tray mesh sheet is sandwiched between the tray outer frame and the tray inner frame, a plurality of third ventilation holes are formed on the tray mesh sheet, and a size of the plurality of third ventilation holes is smaller than the size of the particles of the desiccant.

11. The desiccant box module according to claim 10, wherein a first stiffness of the tray outer frame is greater than or equal to a second stiffness of the tray inner frame, and the second stiffness of the tray inner frame is greater than or equal to a third stiffness of the tray mesh sheet.

12. The desiccant box module according to claim 10, wherein each of the plurality of trays further comprises a plurality of second handles disposed on a plurality of inner surfaces of the tray outer frame.

13. The desiccant box module according to claim 12, wherein a gap between two of the plurality of trays is greater than or equal to a length that one of the plurality of second handles extends beyond one of the plurality of trays.

14. The desiccant box module according to claim 9, wherein the plurality of trays are arranged parallel to a lateral surface of the case.

15. The desiccant box module according to claim 9, wherein the plurality of trays are arranged parallel to a bottom surface of the case.

16. An immersion cooling apparatus, comprising:
a tank; and
the desiccant box module according to claim 1, disposed in the tank.

17. The immersion cooling apparatus according to claim 16, further comprising: two brackets fixed to an inner wall of the tank, wherein the two brackets are configured to support the desiccant box module.

18. The immersion cooling apparatus according to claim 17, wherein each of the two brackets comprises a latch, the desiccant box module comprises two catches, and the desiccant box module is fixed to the two brackets when the two latches are inserted into the two catches.

19. The immersion cooling apparatus according to claim 16, further comprising a condenser module, wherein a liquid region, a vapor region and an air region are formed in the tank, the vapor region is between the liquid region and the air region, the condenser module is disposed at the vapor region, and the desiccant box module is disposed at the air region.

20. The immersion cooling apparatus according to claim 19, wherein a first opening and a second opening are formed on an upper surface of the tank, a projection the condenser module overlaps with a projection of the first opening, and a projection the desiccant box module overlaps with a projection of the second opening.
